(19) United States
(12) Patent Application Publication
(10) Pub. No.: US 2008/0277313 A1
(43) Pub. Date: Nov. 13, 2008

(54) WAFER SUPPORTER

(76) Inventors: Ta-Yung Sung, Taipei County (TW); Kuo-Hsin Chen, Taoyuan County (TW); Chi-Tsai Chiang, Taipei County (TW)

Correspondence Address: NORTH AMERICA INTELLECTUAL PROPERTY CORPORATION, P.O. BOX 506, MERRIFIELD, VA, 22116, US

(21) Appl. No.: 11/874,184

(22) Filed: Oct. 17, 2007

(30) Foreign Application Priority Data
May 10, 2007 (TW) 096116673

(51) Int. Cl. H01L 21/67; B65D 85/86

(52) U.S. Cl. 206/710

(57) ABSTRACT

A wafer supporter includes a base and a plurality of rods vertically fixed on the base. Each rod includes holders to support a wafer. Each of the holders has a downwardly slanted top surface relative to the corresponding rod for a pre-determined angle so that the wafer lies on the top surface on its rim.

### BACKGROUND OF THE INVENTION

1. Field of the Invention

The present invention relates to a supporter. In particular, the present invention relates to a wafer supporter.

2. Description of the Prior Art

In the semiconductor manufacturing process, wafers are usually placed in a boat to undergo many processes, such as thermal oxidation, deposition or annealing for example. FIG. 1 illustrates a conventional ladder boat. Wafers are placed on the rods 14 of the ladder boat 1 at a proper interval S so that an auto guided vehicle can transport the ladder boat.

A conventional ladder boat 1 includes a base 11, a lid 12, several rods 13 extending upright from the base 11 to engage with two opposite ends of the lid 12 so as to form a frame-like structure and holders 14 respectively formed on inner sides of each of the rods 13 and aligned with one another. The wafer 15 is supported by the two mutually aligned holders 14 to be placed in the ladder boat 1.

Because a large area of the wafer 15 engages with the two mutually aligned holders 14 flaws, thermal expansion or vibrations of the holder 14 all tend to cause micro-scratches on the wafer 15. Particles are often found on the contact areas of the wafer 15 with the holders 14, as shown in FIG. 2.

Because of the micro-scratches and the particles, the wafer manufacturing process is disadvantageously affected and the yield is lowered. In addition, if supported by more than 4 holders, the wafer is in an unstable surface engagement with the ladder boat, which also disadvantageously affects the wafer quality.

### SUMMARY OF THE INVENTION

The present invention provides a “point contact” wafer supporter to let the holders have minimum contact with the wafer.

The present invention provides a “point contact” wafer supporter so that the wafer may have as few micro-scratches as possible.

The present invention provides a “point contact” wafer supporter so that there will be few particles on the wafer.

The present invention provides a “point contact” wafer supporter so that the wafer will not be unstably supported.

The present invention provides a “point contact” wafer supporter in which the holders on the rods support the rim of a wafer by a tilted slope.

The wafer supporter of the present invention includes a base and a plurality of rods vertically fixed on the base. Each rod includes a holder for holding a wafer. The holder has a top surface inclined relative to the base at a pre-determined angle so that the wafer lies on the top surface of the holder on its rim.

The holders support the rim of the wafer by a downwardly tilted slope so that the rim of the wafer is able to be supported by the holders due to the top surface being inclined at a pre-determined angle relative to the base. By doing so, the holders contact the wafer as little as possible such that there are only few micro-scratches and particles on the wafer if there is any. Also, the wafer will not be unstably supported on the holders.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a side view of a conventional ladder boat;

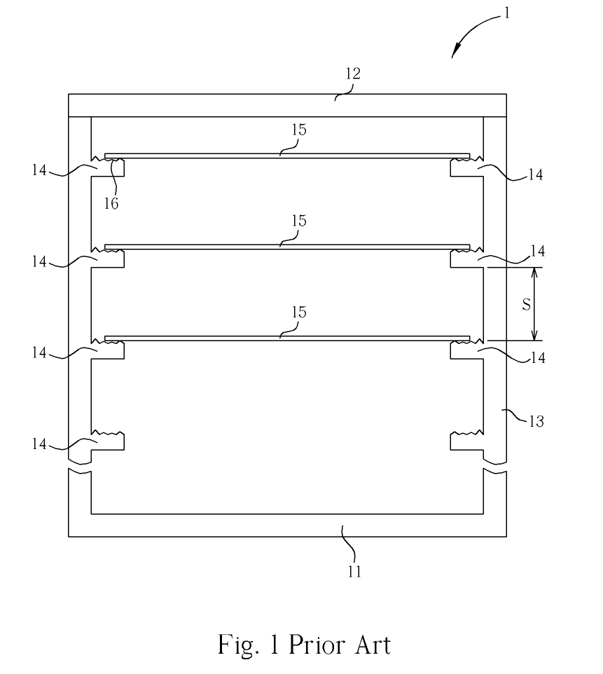

FIG. 2 illustrates particles found on the wafer due to engagement with the conventional ladder boat;

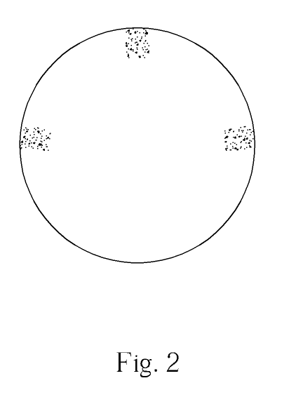

FIG. 3 illustrates a side plan view of the wafer supporter of the present invention.

### DETAILED DESCRIPTION

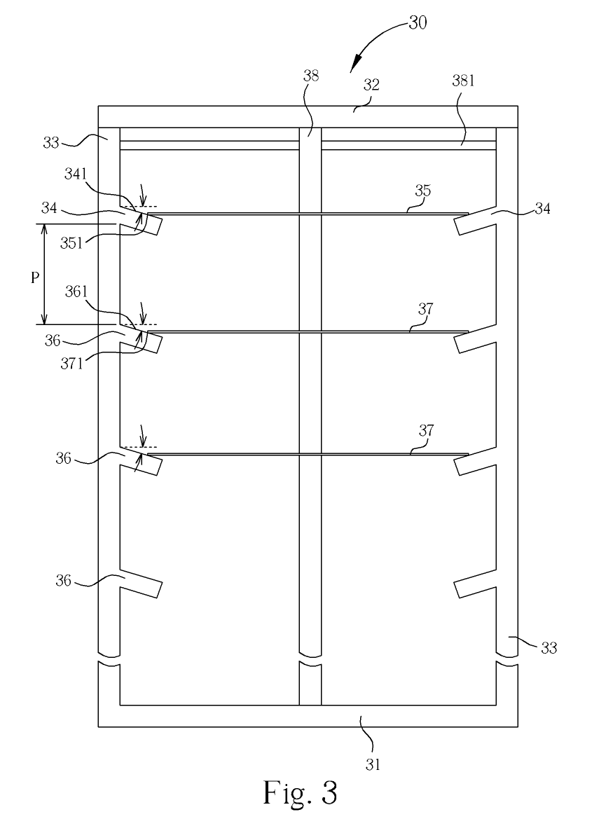

With reference to FIG. 3, it is noted that the wafer supporter 30 of the present invention. includes a base 31 and a plurality of rods 33 securely fixed and extended upright on the base 31. Each supporter 33 includes holders 34 to support wafers 35. The holder 34 has a tilted top surface 341 inclined downward relative to the holder 34 for a pre-determined angle so that only peripheral edge 351 of the wafer 35 engages with the top surface 341.

From the showing of the attached drawing, it is noted that the wafer supporter of the present invention has at least three rods 33 respectively extended upright from the base 31 and having multiple holders 34,36 integrally formed on an inner side face of the rod 33. It is to be noted that there are multiple sets of at least three holders 34,36 aligned with one another to form a supporting surface. Thus the wafer 35,37 may engage with each one of the at least three holders 34,36 which are located at the same height with respect to one another. Due to the tilted top surface 361 and downwardly tilted top surface 341 of the holders 34,36, when the wafer 35,37 is situated on one set of the at least three holders 34,36, only the peripheral edge 351,371 of the wafer 35,37 engages with each holder 34,36 of the supporting surface.

The size and/or the quantity of the holder 34,36 varies depending on the situation. For example, the length of the holder 34,36 may independently be 2.5 mm-15 mm, preferably 8 mm. The distance P between the holder 34 and the holder 36 is at the discretion of persons of ordinary skill in the art. For example, the distance P may be 3.4 mm to 3.6 mm, preferably 3.5 mm.

The inclined angle of the top surface 341/361 depends on the situation, too. For example, the incline angle of the top surface 341,361 may be independently between 1-25°, preferably 3°.

Optionally, the wafer supporter 30 may further include at least one auxiliary rod 38 attached to one of the at least three rods 33 and extending through the beam 381 of the lid 32 and engaging with the base 31. The auxiliary rod 38 has no holder and serves to help strengthen the integrity of the wafer supporter 30 of the present invention and to help stabilize the at least three rods 33. In addition to the lid 32 on top of each of the at least three rods 33 as well as the auxiliary rod 38, an opening is defined in a side face of the wafer supporter 30 to allow the user to place wafers 35,37 inside the wafer supporter 30 or take them out of the wafer supporter 30.

Because the wafer supporter 30 usually accompanies the wafer to undergo various processes, each rod 33/38 may preferably include a thermally-stable inorganic material, such as Si, silicon oxide or silicon carbide.

Because the wafer lies on the top surface 341,361 on its peripheral edge 351/371 by way of point contact, the active area of the wafer will not be damaged no matter which side the wafer is placed in the wafer supporter 30 of the present invention.

Those skilled in the art will readily observe that numerous modifications and alterations of the device and method may be made while retaining the teachings of the invention.

What is claimed is:

1. In a wafer supporter having a base, a lid, multiple rods securely extending upright from the base and engaging with the lid and multiple holders formed on an inner side of each of the rods so as to form a supporting surface to support a wafer, wherein the improvement comprises:
each of the holders is downwardly formed on the inner side of each of the rods such that only a peripheral edge of the wafer engages with each of the holders and micro-scratches on the wafer are avoided.

2. The wafer supporter as claimed in claim 1, wherein each of the holders has a top surface slanted downward relative to a corresponding one of the rods so that when the wafer is placed on top of the top faces of the holders, only the peripheral edge of the wafer is in engagement with the holders.

3. The wafer supporter as claimed in claim 1, wherein each of the holders is slanted relative to a corresponding one of the rods for 1°-25°.

4. The wafer supporter as claimed in claim 2, wherein each of the holders is slanted relative to a corresponding one of the rods for 1°-25°.

5. The wafer supporter of claim 4, wherein the holder is slanted downwardly for 3 degrees.

6. The wafer supporter as claimed in claim 1, wherein a distance between two adjacent rods is from 2.5 mm-15 mm.

7. The wafer supporter as claimed in claim 2, wherein a distance between two adjacent rods is from 2.5 mm-15 mm.

8. The wafer supporter as claimed in claim 3, wherein a distance between two adjacent rods is from 2.5 mm-15 mm.

9. The wafer supporter as claimed in claim 4, wherein a distance between two adjacent rods is from 2.5 mm-15 mm.

10. The wafer supporter as claimed in claim 5, wherein a distance between two adjacent rods is from 2.5 mm-15 mm.

11. The wafer supporter as claimed in claim 4 further comprising an auxiliary rod adapted to connect to the base and the lid to stabilize the rods.

12. The wafer supporter as claimed in claim 6 further comprising an auxiliary rod adapted to connect to the base and the lid to stabilize the rods.
